(19) United States
(12) Patent Application Publication
(10) Pub. No.: US 2019/0276929 A1
(43) Pub. Date: Sep. 12, 2019

(54) METHODS AND APPARATUS FOR PHYSICAL VAPOR DEPOSITION VIA LINEAR SCANNING WITH AMBIENT CONTROL

(71) Applicant: APPLIED MATERIALS, INC., Santa Clara, CA (US)

(72) Inventors: Bencherki Mebarki, SANTA CLARA, CA (US); Joung Joo Lee, SAN JOSE, CA (US); Xianmin Tang, SAN JOSE, CA (US)

(21) Appl. No.: 16/295,817

(22) Filed: Mar. 7, 2019

Related U.S. Application Data
(60) Provisional application No. 62/641,017, filed on Mar. 9, 2018.

(51) Int. Cl. C23C 14/50; H01L 21/02; C23C 14/35; H01J 37/34; C23C 14/54

(52) U.S. Cl. CPC C23C 14/505; H01L 21/02266; C23C 14/54; H01J 37/3432; C23C 14/352

(57) ABSTRACT

Methods and apparatus for physical vapor deposition (PVD) are provided herein. In some embodiments, an apparatus includes a linear PVD source to provide a stream of material flux comprising material to be deposited on a substrate; and a substrate support for supporting the substrate at a non-perpendicular angle to the linear PVD source, and wherein the substrate support and linear PVD source are movable with respect to each other either along a plane of the support surface, or along an axis that is perpendicular to the plane of the support surface, sufficiently to cause the stream of material flux to move completely over a surface of the substrate disposed on the substrate support during operation, wherein the substrate support moves on at least one of a linear slide or shaft that is supported by and travels through a gas-cushioned bearing having an inert gas as a cushioning gas.

### CROSS-REFERENCE TO RELATED APPLICATIONS

This application claims benefit of U.S. provisional patent application Ser. No. 62/641,017, filed Mar. 9, 2018, which is herein incorporated by reference in its entirety.

### FIELD

Embodiments of the present disclosure generally relate to substrate processing equipment, and more particularly, to methods and apparatus for depositing materials via physical vapor deposition.

### BACKGROUND

The semiconductor processing industry generally continues to strive for increased uniformity of layers deposited on substrates. For example, with shrinking circuit sizes leading to higher integration of circuits per unit area of the substrate, increased uniformity is generally seen as desired, or required in some applications, in order to maintain satisfactory yields and reduce the cost of fabrication. Various technologies have been developed to deposit layers on substrates in a cost-effective and uniform manner, such as chemical vapor deposition (CVD) or physical vapor deposition (PVD).

However, the inventor has observed that with the drive to produce equipment to deposit more uniformly, certain applications may not be adequately served where purposeful deposition is required that is not symmetric or uniform with respect to the given structures being fabricated on a substrate.

Accordingly, the inventor has provided improved methods and apparatus for depositing materials via physical vapor deposition.

### SUMMARY

Methods and apparatus for physical vapor deposition (PVD) are provided herein. In some embodiments, an apparatus for physical vapor deposition (PVD) includes a linear PVD source to provide a stream of material flux comprising material to be deposited on a substrate; and a substrate support having a support surface to support the substrate, wherein the substrate support is configured to support the substrate at a non-perpendicular angle to the linear PVD source, and wherein the substrate support and linear PVD source are movable with respect to each other either along a plane of the support surface of the substrate support, or along an axis that is perpendicular to the plane of the support surface of the substrate support, sufficiently to cause the stream of material flux to move completely over a surface of the substrate disposed on the substrate support during operation, wherein the substrate support moves on at least one of a linear slide or shaft that is supported by and travels through a gas-cushioned bearing having an inert gas as a cushioning gas.

In accordance with at least some embodiments of the present disclosure, there is provided a method for performing physical vapor deposition (PVD). The method includes providing a stream of material flux comprising a material to be deposited on a substrate into a processing volume of a PVD chamber by a linear PVD source; supporting the substrate, at a non-perpendicular angle to the linear PVD source, using a substrate support disposed within the processing volume, wherein the substrate support moves on at least one of a linear slide or shaft that is supported by and travels through a gas-cushioned bearing having an inert gas as a cushioning gas; and causing the stream of material flux to move over and be deposited on a working surface of the substrate by moving the substrate support along a plane of a support surface of the substrate support or along an axis that is perpendicular to the plane of the support surface of the substrate support.

In accordance with at least some embodiments of the present disclosure, there is provided a nontransitory computer readable storage medium having stored thereon instructions which when executed by a controller perform a method for physical vapor deposition (PVD). The method includes providing a stream of material flux comprising a material to be deposited on a substrate into a processing volume of a PVD chamber by a linear PVD source; supporting the substrate, at a non-perpendicular angle to the linear PVD source, using a substrate support disposed within the processing volume, wherein the substrate support moves on at least one of a linear slide or shaft that is supported by and travels through a gas-cushioned bearing having an inert gas as a cushioning gas; and causing the stream of material flux to move over and be deposited on a working surface of the substrate by moving the substrate support along a plane of the support surface of the substrate support or along an axis that is perpendicular to the plane of the support surface of the substrate support.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIGS. 1A-1B are schematic side and top views, respectively, of an apparatus for physical vapor deposition in accordance with at least some embodiments of the present disclosure.

FIG. 2A is a schematic side view of a feature having a layer of material deposited thereon in accordance with at least some embodiments of the present disclosure.

FIG. 2B is a schematic side view of a substrate having a plurality of features having a layer of material deposited thereon, as depicted in FIG. 2A, in accordance with at least some embodiments of the present disclosure.

FIG. 2C is a schematic side view of a feature having a layer of material deposited thereon in accordance with at least some embodiments of the present disclosure.

FIG. 2D is a schematic side view of a substrate having a plurality of features having a layer of material deposited thereon, as depicted in FIG. 2C, in accordance with at least some embodiments of the present disclosure.

FIGS. 3A-3B are two dimensional and three dimensional schematic side views of an apparatus for physical vapor deposition in accordance with at least some embodiments of the present disclosure.

FIGS. 3C-3D respectively depict schematic top and isometric cross-sectional views of a substrate support and deposition structure of an apparatus for physical vapor deposition in accordance with at least some embodiments of the present disclosure.

FIG. 4 is a schematic side view of an apparatus for physical vapor deposition in accordance with at least some embodiments of the present disclosure.

FIGS. 5A-5B are schematic side and top views, respectively, of an apparatus for physical vapor deposition in accordance with at least some embodiments of the present disclosure.

FIG. 6 is a schematic side view of an apparatus for physical vapor deposition in accordance with at least some embodiments of the present disclosure.

FIG. 7 is a schematic side view of an apparatus for physical vapor deposition in accordance with at least some embodiments of the present disclosure.

FIG. 8 is a schematic side view of an apparatus for physical vapor deposition in accordance with at least some embodiments of the present disclosure.

FIG. 9 is a schematic side view of an apparatus for physical vapor deposition in accordance with at least some embodiments of the present disclosure.

FIG. 10 is a flowchart of a method for performing physical vapor deposition in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of methods and apparatus for physical vapor deposition (PVD) are provided herein. Embodiments of the disclosed methods and apparatus advantageously enable uniform angular deposition of materials on a substrate. In such applications, deposited materials are asymmetric or angular with respect to a given feature on a substrate, but can be relatively uniform within all features across the substrate. Embodiments of the disclosed methods and apparatus advantageously enable new applications or opportunities for selective PVD of materials, thus further enabling new markets and capabilities.

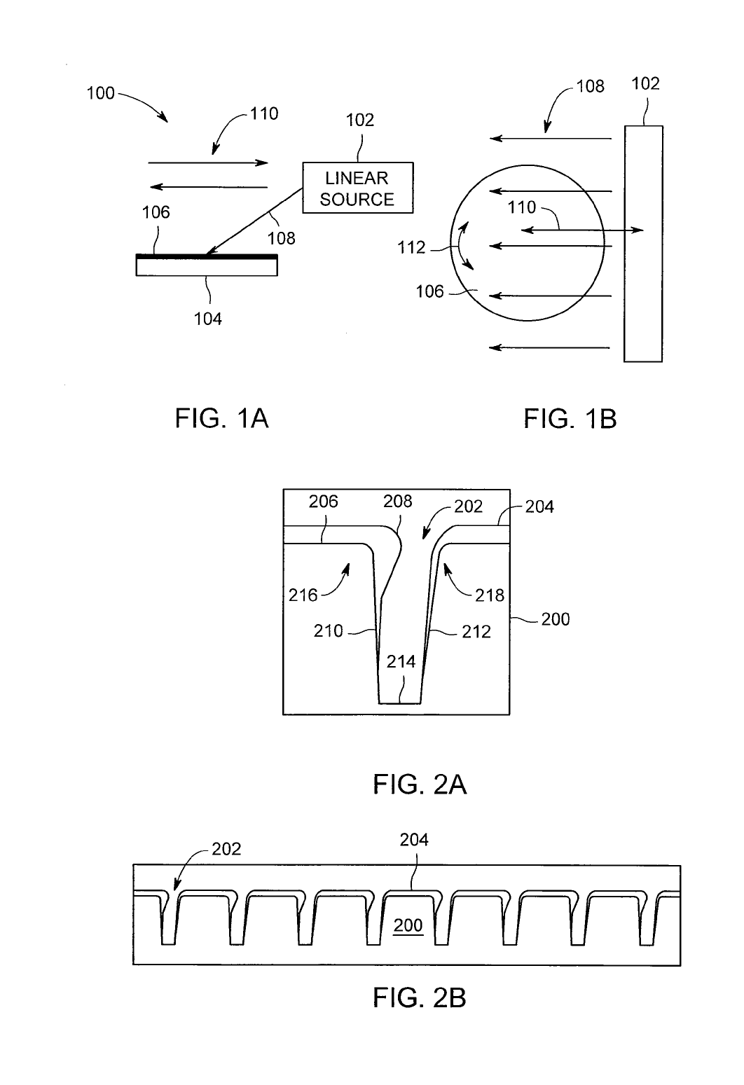

FIGS. 1A-1B are schematic side and top views, respectively, of an apparatus 100 for PVD in accordance with at least some embodiments of the present disclosure. Specifically, FIGS. 1A-1B schematically depict an apparatus 100 for PVD of materials on a substrate at an angle to the generally planar surface of the substrate. The apparatus 100 generally includes a linear PVD source 102 and a substrate support 104 for supporting a substrate 106. The linear PVD source 102 is configured to provide a directed stream of material flux (stream 108 as depicted in FIGS. 1A-1B) from the source toward the substrate support 104 (and any substrate 106 disposed on the substrate support 104). The substrate support 104 has a support surface to support the substrate 106 such that a working surface of the substrate 106 to be deposited on is exposed to the directed stream 108 of material flux. The stream 108 of material flux provided by the linear PVD source 102 has a width greater than that of the substrate support 104 (and any substrate 106 disposed on the substrate support 104). The stream 108 of material flux has a linear elongate axis corresponding to the width of the stream 108 of material flux. The substrate support 104 and the linear PVD source 102 are configured to move linearly with respect to each other, as indicated by arrows 110. The relative motion can be accomplished by moving either or both of the linear PVD source 102 or the substrate support 104. Optionally, the substrate support 104 may additionally be configured to rotate (for example, within the plane of the support surface), as indicated by arrows 112.

The linear PVD source 102 includes target material to be sputter deposited on the substrate 106. In some embodiments, the target material can be, for example, a metal, such as titanium, or the like, suitable for depositing titanium (Ti) or titanium nitride (TiN) on the substrate 106. In some embodiments, the target material can be, for example, silicon, or a silicon-containing compound, suitable for depositing silicon (Si), silicon nitride (SiN), silicon oxynitride (SiON), or the like on the substrate. Other materials may suitably be used as well in accordance with the teachings provided herein. The linear PVD source 102 further includes, or is coupled to, a power source to provide suitable power for forming a plasma proximate the target material and for sputtering atoms off of the target material. The power source can be either or both of a DC or an RF power source.

Unlike an ion beam or other ion source, the linear PVD source 102 is configured to provide mostly neutrals and few ions of the target material. As such, a plasma may be formed having a sufficiently low density to avoid ionizing too many of the sputtered atoms of target material. For example, for a 300 mm diameter wafer as the substrate 106, about 1 to about 20 kW of DC or RF power may be provided. The power or power density applied can be scaled for other size substrates. In addition, other parameters may be controlled to assist in providing mostly neutrals in the stream 108 of material flux. For example, the pressure may be controlled to be sufficiently low so that the mean free path is longer than the general dimensions of an opening of the linear PVD source 102 through which the stream 108 of material flux passes toward the substrate support 104 (as discussed in more detail below). In some embodiments, the pressure may be controlled to be about 0.5 to about 5 millitorr.

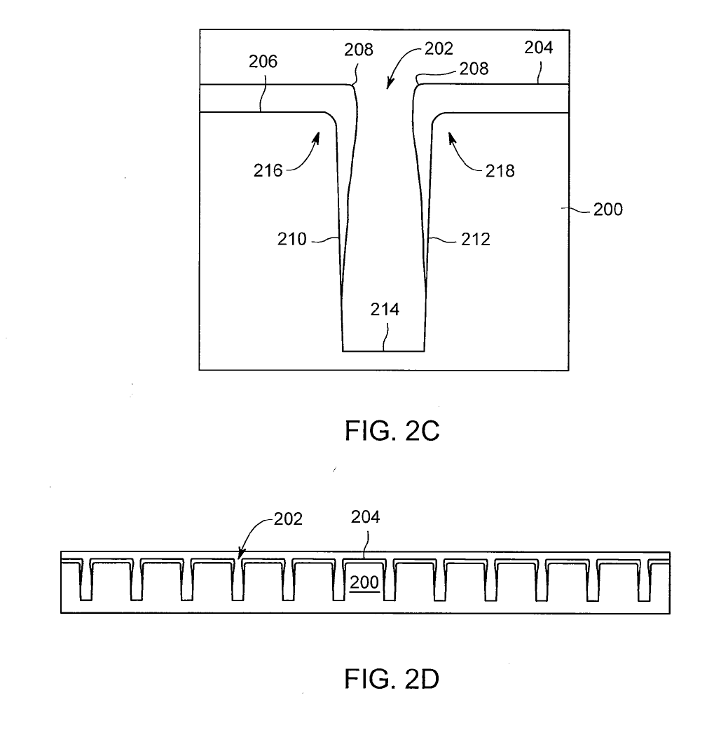

The methods and embodiments disclosed herein advantageously enable deposition of materials with a shaped profile, or in particular, with an asymmetric profile with respect to a given feature on a substrate, while maintaining overall deposition and shape uniformity across all features on a substrate. For example, FIG. 2A depicts a schematic side view of a substrate 200 including a feature 202 having a layer of material 204 deposited thereon in accordance with at least some embodiments of the present disclosure. The feature 202 can be a trench, a via, or dual damascene feature, or the like. In addition, the feature 202 can protrude from the substrate rather than extend into the substrate 200. The material 204 is deposited not just atop a top surface 206 of the substrate 200 (e.g., the field region), but also within or along at least portions of the feature 202 as well. However, the material 204 is deposited to a greater thickness on a first side 210 of the feature as compared to an opposing second side 212 of the feature (as depicted by portion 208 of material). In some embodiments, and depending upon the incoming angle of the stream 108 of material flux, the material 204 can be deposited on a bottom 214 of the feature. In some embodiments, and as depicted in FIG. 2A, little or no material 204 is deposited on a bottom 214 of the feature 202. In some embodiments, additional material 204 is deposited particularly near an upper corner 216 of the first side 210 of the feature 202, as compared to an opposite upper corner 218 of the second side 212 of the feature 202.

As shown in FIG. 2B, which is a schematic side view of the substrate 200 having a plurality of features 202 having a layer of material 204 deposited thereon in accordance with at least some embodiments of the present disclosure, the material 204 is deposited relatively uniformly across a plurality of features 202 formed in the substrate 200. As shown in FIG. 2B, the shape of the deposited material 204 is substantially uniform from feature to feature across the substrate 200, but is asymmetric within any given feature 202. Thus, embodiments in accordance with the present disclosure advantageously provide controlled/uniform angular deposition of the material 204 on the substrate 200 with a substantially uniform amount of the material 204 deposited on a field region of the substrate 200.

In some embodiments, for example where the substrate support 104 is configured to rotate in addition to moving linearly with respect to the linear PVD source 102, different profiles of material deposition can be provided. For example, FIG. 2C depicts a schematic side view of the substrate 200 including the feature 202 having a layer of material 204 deposited thereon in accordance with at least some embodiments of the present disclosure. As described above with respect to FIGS. 2A-2B, the material 204 is deposited not just atop the top surface 206 of the substrate 200 (e.g., the field region), but also within or along at least portions of the feature 202 as well. However, in embodiments consistent with FIG. 2C, the material 204 is deposited to a greater thickness on both the first side 210 of the feature as well as the opposing second side 212 of the feature (as depicted by portion 208 of material) as compared to the bottom 214 of the feature 202. In some embodiments, and depending upon the incoming angle of the stream 108 of material flux, the amount of materials deposited on lower portions of the sidewall and the bottom 214 of the feature can be controlled. However, as depicted in FIG. 2C, little or no material 204 is deposited on the bottom 214 of the feature 202 (as well as on the lower portion of the sidewalls proximate the bottom 214).

As shown in FIG. 2D, which is a schematic side view of the substrate 200 having the plurality of features 202 having the layer of material 204 deposited thereon in accordance with at least some embodiments of the present disclosure, the material 204 is deposited relatively uniformly across the plurality of features 202 formed in the substrate 200. As shown in FIG. 2D, the shape of the deposited material 204 is substantially uniform from feature to feature across the substrate 200, but with a controlled material profile within any given feature 202. Thus, embodiments in accordance with the present disclosure advantageously provide controlled/uniform angular deposition of the material 204 on the substrate 200 with a substantially uniform amount of the material 204 deposited on a field region of the substrate 200.

Although the above description of FIGS. 2A-2D refer to the feature 202 having sides (e.g., a first side 210 and a second side 212), the feature 202 can be circular (such as a via). In such cases where the feature 202 is circular, although the feature 202 may have a singular sidewall, the first side 210 and second side 212 can be arbitrarily selected/controlled based upon the orientation of the substrate 200 with respect to the linear axis of movement of the substrate support 104 and direction of the stream 108 of material flux from the linear PVD source 102. Moreover, in embodiments where the substrate support 104 can rotate, the first side 210 and second side 212 can change, or be blended, dependent upon the orientation of the substrate 200 during processing.

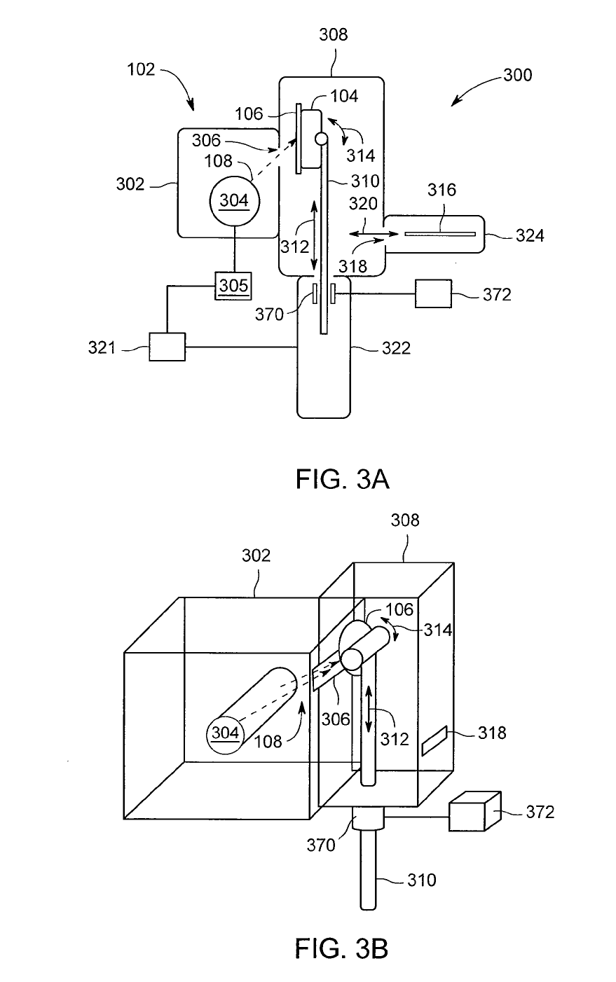

The above apparatus 100 can be implemented in numerous ways, and several non-limiting embodiments are provided herein in FIG. 3A through FIG. 12. While different Figures may discuss different features of the apparatus 100, combinations and variations of these features may be made in keeping with the teachings provided herein. In addition, although the Figures may show an apparatus having a particular orientation (e.g., vertical or horizontal), such orientations are examples and not limiting of the disclosure. For example, any configuration can be rotated or oriented differently than as shown on the page. FIGS. 3A-3B are two dimensional and three dimensional schematic side views of an apparatus 300 for physical vapor deposition in accordance with at least some embodiments of the present disclosure. Certain items shown in FIG. 3A have been removed from FIG. 3B to enhance the clarity of the disclosure. The apparatus 300 is an exemplary implementation of the apparatus 100 and discloses several exemplary features.

As depicted in FIGS. 3A-3B, the linear PVD source 102 may include a chamber or housing 302 having an interior volume. A target 304 of source material to be sputtered is disposed within the housing 302. The target 304 is generally elongate and can be, for example, cylindrical or rectangular. The target 304 size can vary depending upon the size of the substrate 106 and the configuration of the processing chamber. For example, for processing a 300 mm diameter semiconductor wafer, the target 304 can be between about 100 to about 200 mm in width or diameter, and can have a length of about 400 to about 600 mm. The target 304 can be stationary or movable, including rotatable along the elongate axis of the target 304.

The target 304 is coupled to a power source 305. A gas supply (not shown) may be coupled to the interior volume of the housing 302 to provide a gas, such as an inert gas (e.g., argon) or nitrogen (N₂) suitable for forming a plasma within the interior volume when sputtering material from the target 304 (creating the stream 108 of material flux). The housing 302 is coupled to a deposition chamber 308 containing the substrate support 104. A vacuum pump can be coupled to an exhaust port (not shown) in at least one of the housing 302 or the deposition chamber 308 to control the pressure during processing.

An opening 306 couples the interior volumes of the housing 302 and the deposition chamber 308 to allow the stream 108 of material flux to pass from the housing 302 into the deposition chamber 308, and onto the substrate 106. As discussed in more detail below, the position of the opening 306 with respect to the target 304 as well as the dimensions of the opening 306 can be selected or controlled to control the shape and size of the stream 108 of material flux passing though the opening 306 and into the deposition chamber 308. For example, the length of the opening 306 is wide enough to allow the stream 108 of material flux to be wider than the substrate 106. In addition, the width of the opening 306 may be controlled to provide an even deposition rate along the length of the opening 306 (e.g., a wider opening 306 may provide greater deposition uniformity, while a narrower opening 306 may provide increased control over the angle of impingement of the stream 108 of material flux on the substrate 106). In some embodiments, a plurality of magnets may be positioned proximate the target 304 to control the position of the plasma with respect to the target 304 during processing. The deposition process can be tuned by controlling the plasma position (e.g., via the magnet position), and the size and relative position of the opening 306.

The housing 302 can include a liner of suitable material to retain particles deposited on the liner to reduce or eliminate particulate contamination on the substrate 106. The liner can be removable to facilitate cleaning or replacement. Similarly, a liner can be provided to some or all of the deposition chamber 308, for example, at least proximate the opening 306. The housing 302 and the deposition chamber 308 are typically grounded.

In the embodiment depicted in FIGS. 3A-3B the linear PVD source 102 is stationary and the substrate support 104 is configured to linearly move. For example, the substrate support 104 is coupled to a linear slide 310 that can move linearly back and forth sufficiently within the deposition chamber 308 to allow the stream 108 of material flux to impinge upon desired portions of the substrate 106, such as the entire substrate 106. The linear slide 310 can travel through a bearing 370, such as a gas-cushioned bearing. The inventors have observed that when air, or clean dry air (CDA), is used as the cushioning gas for the gas-cushioned bearing, oxygen in the air (e.g., O₂, H₂O, or the like) can leak into the inner volume of the deposition chamber 308 and can cause defects in the deposited film, such as by oxidation. As such, an inert gas source 372 is coupled to the bearing 370 to provide an inert gas to the bearing, rather than air or CDA. The inert gas can be a noble gas, such as argon, helium, or the like. In some embodiments, for example where nitrogen is not an undesirable element in the film being deposited, the inert gas can be nitrogen gas (N₂).

A position control mechanism 322, such as an actuator, motor, drive, or the like, controls the position of the substrate support 104, for example, via the linear slide 310. The substrate may be moved linearly along a plane such that the surface of the substrate 106 is maintained at a perpendicular distance of about 1 to about 10 mm from the opening 306. The substrate support 104 can be moved at a rate to control the deposition rate on the substrate 106. For example, a controller 321 can be operatively coupled to the position control mechanism 322, to the power source 305, or to both the position control mechanism 322 and/or the power source 305. The controller 321 includes a central processing unit (CPU), support circuits, and a computer readable medium (e.g., a nontransitory computer readable storage medium), or memory. The computer readable storage medium can be configured to store instructions that when executed by the controller can perform a method for performing physical vapor deposition on a substrate (e.g., the substrates 106, 200), as will be described in greater detail below.

Optionally, the substrate support 104 can also be configured to rotate within the plane of the support surface, such that a substrate disposed on the substrate support 104 can be rotated. A rotation control mechanism, such as an actuator, motor, drive, or the like, controls the rotation of the substrate support 104 independent of the linear position of the substrate support 104. Accordingly, the substrate support 104 can be rotated while the substrate support 104 is also moving linearly through the stream 108 of material flux during operation. Alternatively, the substrate support 104 can be rotated between linear scans of the substrate support 104 through the stream 108 of material flux during operation (e.g., the substrate support can be moved linearly without rotation, and rotated while not moving linearly).

In addition, the substrate support 104 can move to a position for loading and unloading of substrates 106 into and out of the deposition chamber 308. For example, in some embodiments, a transfer chamber 324, such as a load lock, may be coupled to the deposition chamber 308 via a slot or opening 318. A substrate transfer robot 316, or other similar suitable substrate transfer device, can be disposed within the transfer chamber 324 and movable between the transfer chamber 324 and the deposition chamber 308, as indicated by arrows 320, to move substrates 106 into and out of the deposition chamber 308 (and onto and off of the substrate support 104). In embodiments where the substrate support 104 has a different orientation required for deposition and transfer, the substrate support 104 can further be rotatable or otherwise movable, as indicated by arrows 314. For example, in the embodiments depicted in FIGS. 3A-3B, the substrate support 104 can be in a horizontal, and lower, position (in terms of the Figures) when moving substrates 106 between the substrate support 104 and the transfer chamber 324. In addition, the substrate support 104 can be in a vertical, and upper, position (in terms of the Figures) when moving the substrate 106 relative to the stream 108 of material flux to deposit materials atop the substrate 106.

Depending upon the configuration of the substrate support 104, and in particular of the support surface of the substrate support 104 (e.g., vertical, horizontal, or angled), the substrate support 104 may be configured appropriately to retain the substrate 106 during processing. For example, in some embodiments, the substrate 106 may rest on the substrate support 104 via gravity. In some embodiments, the substrate 106 may be secured onto the substrate support 104, for example, via a vacuum chuck, an electrostatic chuck, mechanical clamps, or the like. Substrate guides and alignment structures may also be provided to improve alignment and retention of the substrate 106 on the substrate support 104.

FIGS. 3C-3D respectively depict schematic top and isometric cross-sectional views of a substrate support and deposition structure of an apparatus for physical vapor deposition in accordance with at least some embodiments of the present disclosure. FIG. 3D is an isometric cross-sectional view of the substrate support and deposition structure taken along line I-I in FIG. 3C.

A deposition structure 326 may be disposed around the substrate 106 and the substrate support 104 within the deposition chamber 308. For example, the deposition structure 326 may be coupled to the substrate support 104. In some embodiments, the deposition structure 326 and a front surface of the substrate 106 form a common planar surface. The deposition structure 326 reduces deposits or particles from accumulating on the edge and backside of the substrate 106 during the scanning of the substrate 106. Furthermore, use of the deposition structure 326 reduces deposits or particles from accumulating on the substrate support 104 and hardware and equipment in the vicinity of the substrate support 104. In some embodiments, a voltage source (not shown) may be coupled to a portion of the deposition structure 326 to apply a charge to a portion of the deposition structure 326. In some embodiments, the voltage source may be used to apply a voltage or charge to a removable structure 328 associated with the deposition structure 326. Although the stream 108 of material flux comprises mostly neutrals, applying a charge to the portion of the deposition structure 326 or the removable structure 328 may further reduce deposits or particles that accumulate on the edge and backside of the substrate 106 during the scanning of the substrate 106 due to any ionized particles.

In some embodiments, the deposition structure 326 includes the removable structure 328 disposed in an opening 330 of the deposition structure 326. The removable structure 328 can have a shape that corresponds to the substrate 106. For example, in embodiments where the substrate 106 is a circular substrate, such as a semiconductor wafer, the removable structure 328 is a removable ring structure. As depicted in FIGS. 3C-3D, the substrate 106 is exposed through the opening 330.

The removable structure 328 has an outside edge surface 332 and an inside edge surface 334. A circumference of the inside edge surface 334 is greater than a circumference of the substrate support 104. Furthermore, in some embodiments, the removable structure 328 has an exterior surface 336 aligned with a front surface 338 of the deposition structure 326. Furthermore, in some embodiments, a front surface 340 of the substrate 106 may be aligned with the front surface 338 of the deposition structure 326 and the exterior surface 336 of the removable structure 328. Therefore, in some embodiments, the exterior surface 336 of the removable structure 328, the front surface 338 of the deposition structure 326, and the front surface 340 of the substrate 106 form a planar surface. In some embodiments, the exterior surface 336 is not aligned with the front surface 338 of the deposition structure 326 and/or the front surface 340 of the substrate 106.

As depicted in FIG. 3D, the removable structure 328 includes a groove 342. The groove 342 may be formed in at least a portion of a circumference of the removable structure 328. In some embodiments, the groove 342 is formed in the entire circumference of the removable structure 328. The groove 342 may include an angled surface 344 functional to direct the particles associated with the stream 108 of material flux away from a backside 346 of the substrate 106. Moreover, the angled surface 344 is functional to direct particles associated with the stream 108 of material flux away from the substrate support 104. In some embodiments, particles associated with the stream 108 of material flux may be directed by the angled surface 344 toward a surface 348 associated with the groove 342. The groove 342 may be formed having a shallower or deeper depth than shown in FIG. 3.

Furthermore, while the surface 348 is illustrated as being straight, the surface 348 may alternatively be formed at an angle similar to the angled surface 344.

The removable structure 328 can include a ledge 350. The ledge 350 may be in contact with a backside 352 of the deposition structure 326. In some embodiments, the ledge 350 is removably press fit against the deposition structure 326, on the backside 352 of the deposition structure 326.

In some embodiments, the ledge 350 is coupled to the deposition structure 326, on the backside 352 of the deposition structure 326. For example, the removable structure 328 may include one or more through holes 353. In some embodiments, a plurality of through holes 353 are disposed in the ledge 350. The plurality of through holes 353 may receive a retainer element 356, such as a fastener, screw, or the like. Each of the retainer elements 356 may be received by a hole 358 in the deposition structure 326. Therefore, the deposition structure 326 may include a plurality of the holes 358. In another embodiment, the holes 358 may be through holes so that the retainer elements 356 may be inserted from the front surface 338 of the deposition structure 326 and retainably attached to the ledge 350 using a nut, fastener or threads.

The substrate plane structure having a removable ring is advantageously straightforward to maintain. Specifically, advantageously, rather than removing the entire substrate plane structure when preventive maintenance is required, the removable ring can be removed to complete the required preventative maintenance. Furthermore, because the substrate plane structure and the removable ring pieces advantageously provide a modular unit, the costs associated with maintaining and replacing the modular unit may be advantageously reduced compared to maintaining and replacing conventional substrate plane structures formed as one contiguous unit. In addition, advantageously, removable rings may be made from different materials compared to the remainder of the substrate plan structure. For example, use of particular material types for the removable rings may advantageously mitigate accumulation of deposits and particles on the edge of the wafer.

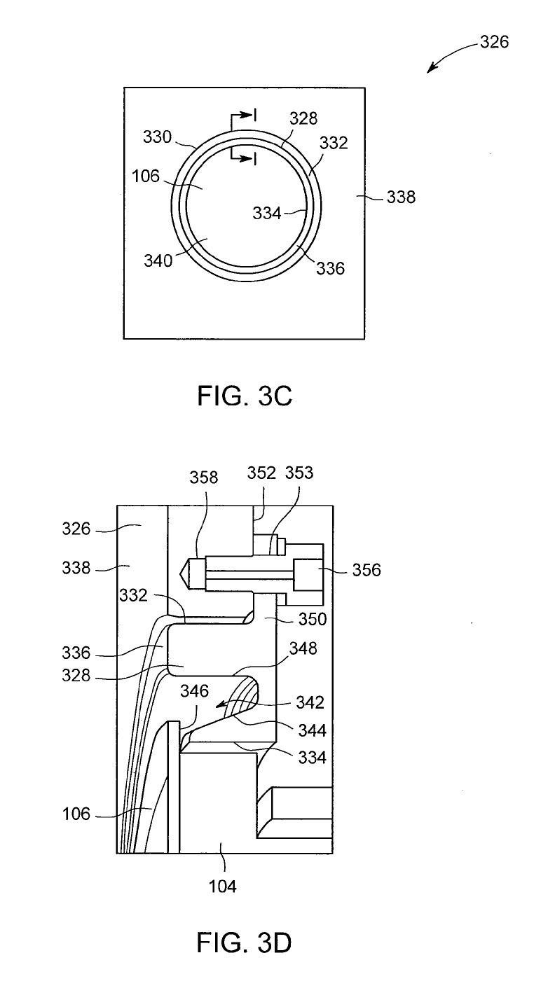

FIG. 4 is a schematic side view of an apparatus 400 for physical vapor deposition in accordance with at least some embodiments of the present disclosure. The apparatus 400 is an exemplary implementation of the apparatus 100 and discloses several exemplary features. The apparatus 400 is similar to and operates in similar fashion as the apparatus 300 described above except that the orientation of the substrate remains constant relative to the deposition and loading/unloading positions, as compared to the orthogonal relative positions in the apparatus 300. In addition, in the orientation of the page, FIGS. 3A-3B depicts a vertically configured system (e.g., the substrate support 104 moves vertically), and FIG. 4 depicts a horizontally configured system (e.g., the substrate support 104 moves horizontally).

As depicted in FIG. 4, a plurality of lift pins 402 can be provided proximate the opening 318 to facilitate transferring the substrate 106 between the substrate support 104 and a substrate transfer robot (e.g., as discussed above with respect to FIGS. 3A-B).

In addition, a target 404 can have a different configuration than the cylindrical target 304 depicted in other Figures. Specifically, the target 404 can be a rectangular target having, for example, a planar rectangular face of target material to be sputtered. The aforementioned target 404 configuration can also be used in any of the other embodiments disclosed herein.

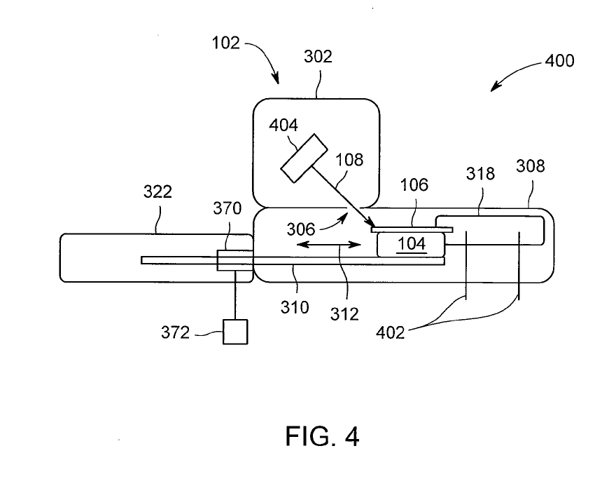

FIGS. 5A-5B are schematic side and top views, respectively, of an apparatus 500 for physical vapor deposition in accordance with at least some embodiments of the present disclosure. The apparatus 500 is an exemplary implementation of the apparatus 100 and discloses several exemplary features. The apparatus 500 is similar to and operates in similar fashion as the apparatus 300 described above except that the linear slide 310 (and position control mechanism 322, not shown) extend from the top of the deposition chamber 308, rather than from the bottom.

In addition, as depicted in FIG. 5B, the linear slide 310 can include a plurality of linear slide members 502. Each linear slide member 502 can be coupled to the substrate support 104 at a first end, for example, via a cross member 504. An opposing end of the linear slide members 502 can be coupled to the position control mechanism 322 to facilitate control of the substrate support 104. Although not shown in FIGS. 5A-5B, the bearing 370 and inert gas source 372 may be provided for each linear slide 310.

In embodiments of a PVD apparatus as disclosed herein, the general angle of incidence of the stream 108 of material flux can be controlled or selected to facilitate a desired deposition profile of material on the substrate 106. In addition, the general shape of the stream 108 of material flux can be controlled or selected to control the deposition profile of material deposited on the substrate 106. In some embodiments, material can be deposited on a top surface of the substrate 106 and a first sidewall of a feature on the substrate 106 (e.g., substantially as depicted in FIGS. 2A and 2B). In some embodiments, depending upon the deposition angle, material can further be deposited on a bottom surface of the feature. In some embodiments, depending upon the deposition angle, material can further be deposited on an opposing sidewall surface of the feature, with greater deposition on a first sidewall as compared to the opposing sidewall of the feature.

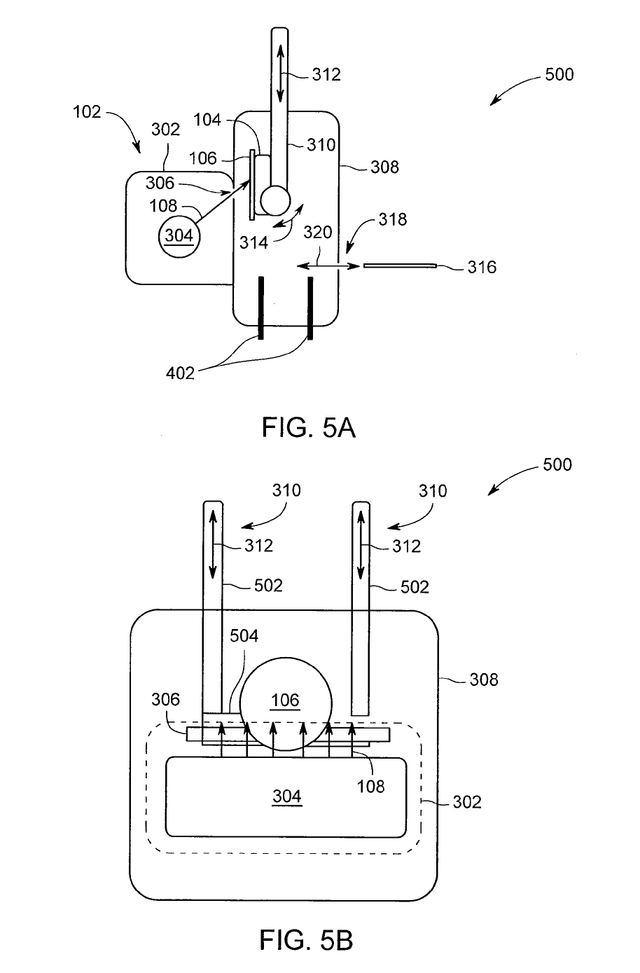

FIG. 6 is a schematic side view of an apparatus for physical vapor deposition in accordance with at least some embodiments of the present disclosure.

In the embodiment depicted in FIG. 6 the substrate support 104 is configured to linearly move along an axis perpendicular to a plane of the support surface of the substrate support 104 (e.g., perpendicular to the plane of the substrate surface). For example, the substrate support 104 is coupled to a shaft 610 that can move linearly back and forth (e.g., closer to and further from the linear PVD source 102) sufficiently to allow the stream 108 of material flux to impinge upon desired portions of the substrate 106, such as the entire substrate 104. A position control mechanism 322, such as an actuator, motor, drive, or the like, controls the position of the substrate support 104, for example, via the shaft 610. As in the embodiment described above with respect to FIG. 3A, the shaft 610 is supported by and travels through bearing 370, such as a gas-cushioned bearing. Inert gas source 372 is coupled to the bearing 370 to provide an inert gas to the bearing, rather than air or CDA, as described above.

The substrate support 104 is movable at least between a first position, closest to the linear PVD source 102 and a second position, further from the linear PVD source 102. The first position is configured such that, in operation, the stream 108 of material flux is proximate a first side of the substrate 106. In the first position, the stream 108 of material flux can either miss the substrate 106 or can impinge upon at least the working surface of the substrate along the first side of the substrate. The second position is configured such that, in operation, the stream 108 of material flux is proximate a second side of the substrate 106, opposite the first side. In the second position, the stream 108 of material flux can either miss the substrate 106 or can impinge upon at least the working surface of the substrate 106 along the second side of the substrate 106. The first and second positions are configured such that motion between the two positions will cause the stream 108 of material flux to move across the substrate 106 from the first side to the second side, thus impinging upon the entire working surface of the substrate 106 over the course of a single scan from the first position to the second position (or from the second position to the first position).

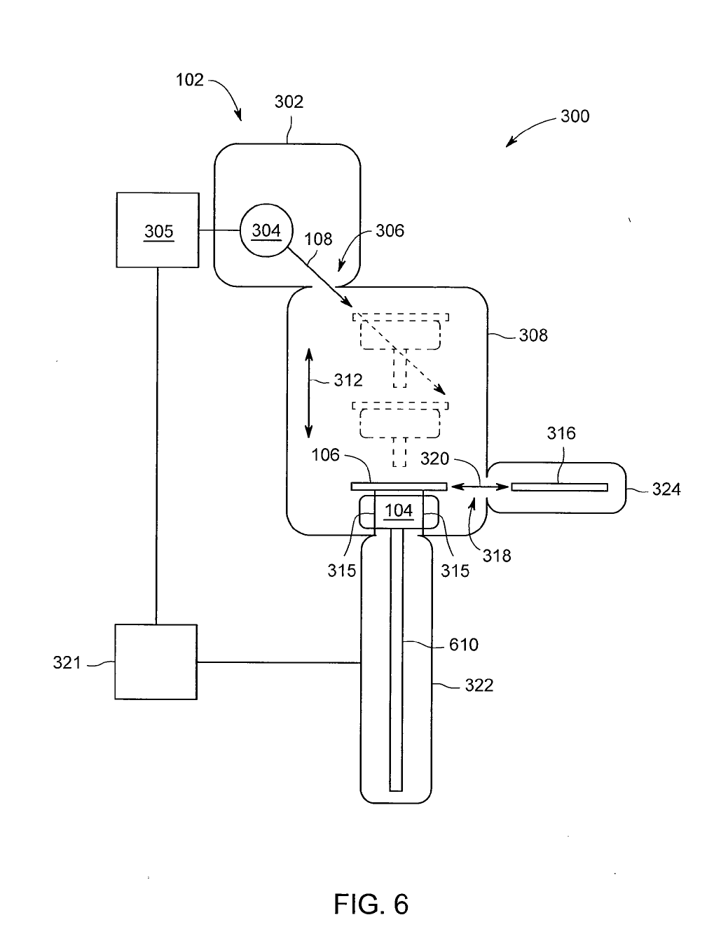

Combinations and variations of the above embodiments include apparatus having more than one target to facilitate deposition at multiple angles. For example, FIG. 7 is a schematic side view of an apparatus for physical vapor deposition in accordance with at least some embodiments of the present disclosure. As depicted in FIG. 7, two linear PVD sources 102, 102′ may be provided, such that targets 304, 304′ can have respective streams 108, 108′ of material flux that are separately directed through respective openings 306, 306′ to impinge of the substrate 106. The target materials can be the same material or different materials. In addition, process gases provided to the separate linear PVD sources 102, 102′ can be the same or different. The size of the targets 304, 304′, location of the targets 304, 304′, location and size of the openings 306, 306′, can be independently controlled to independently control the impingement of materials from each stream 108, 108′ of material flux onto the substrate 106.

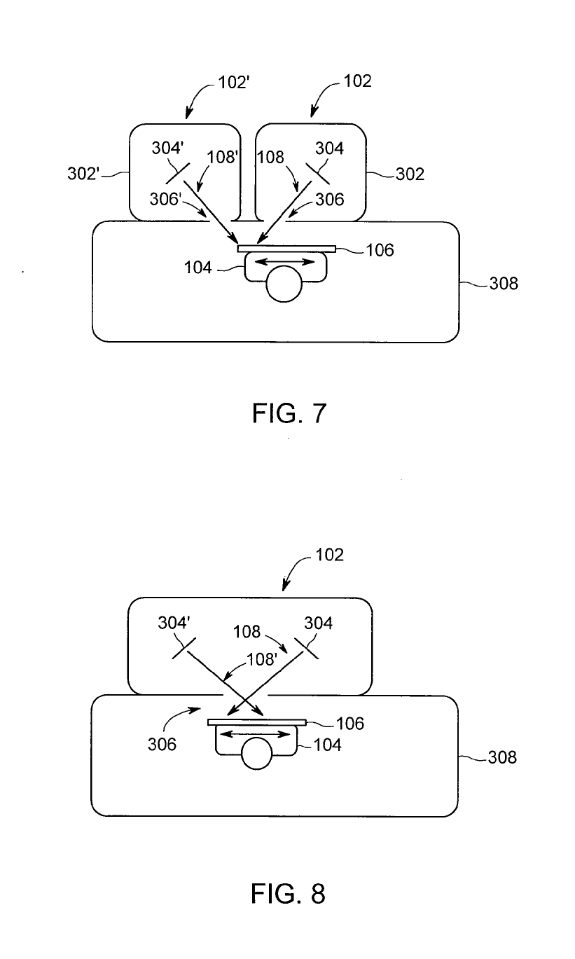

FIG. 8 is a schematic side view of an apparatus for physical vapor deposition in accordance with at least some embodiments of the present disclosure. FIG. 8 is similar to the embodiment of FIG. 7 except that the two targets 304, 304′ are provided within the same linear PVD source 102.

In each of the embodiments of FIGS. 7-8, the relative angles of the targets 304, 304′, and thus the direction of the streams 108, 108′ of material flux are illustrative and other angles can be chosen independently, including in directions such that the targets 304, 304′ are not parallel to each other.

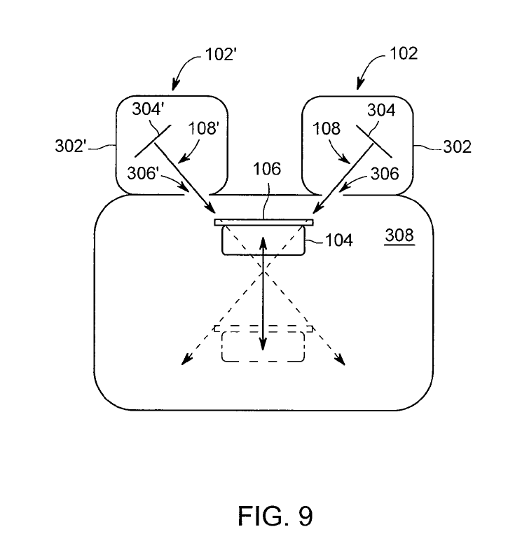

FIG. 9 is a schematic side view of an apparatus for physical vapor deposition in accordance with at least some embodiments of the present disclosure. As depicted in FIG. 9, two linear PVD sources 102, 102′ may be provided, such that targets 304, 304′ can have respective streams 108, 108′ of material flux that are separately directed through respective openings 306, 306′ to impinge of the substrate 106. The target materials can be the same material or different materials. In addition, process gases provided to the separate linear PVD sources 102, 102′ can be the same or different. The size of the targets 304, 304′, location of the targets 304, 304′, location and size of the openings 306, 306′, can be independently controlled to independently control the impingement of materials from each stream 108, 108′ of material flux onto the substrate 106.

The relative angles of the targets 304, 304′, and thus the direction of the streams 108, 108′ of material flux are illustrative and other angles can be chosen independently, including in directions such that the targets 304, 304′ are not parallel to each other. Although not shown in FIGS. 7-9, the bearing 370 and inert gas source 372 may be provided for each linear slide or shaft providing the linear motion to the substrate support 104.

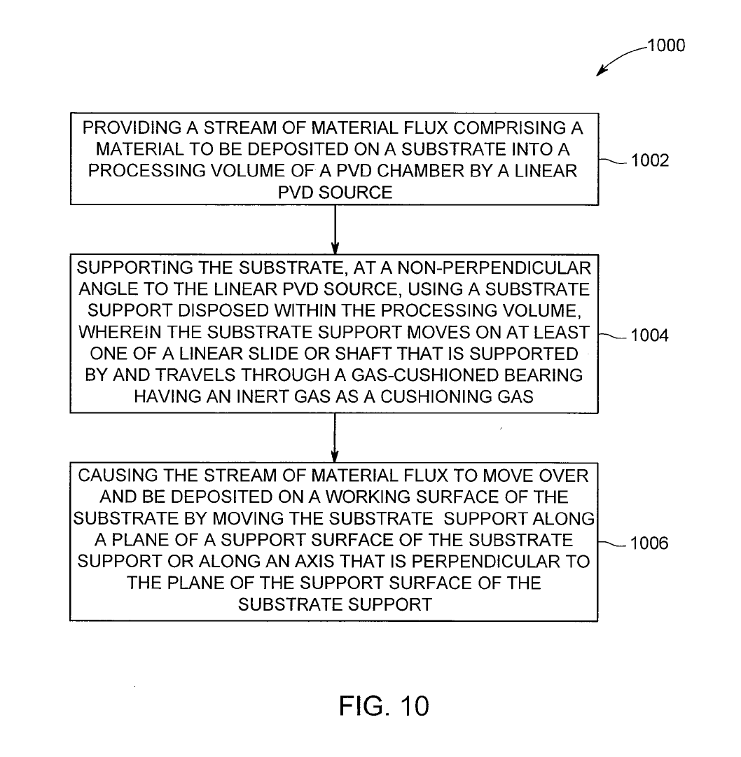

FIG. 10 is a method 1000 for performing physical vapor deposition in accordance with at least some embodiments of the present disclosure. At 1002, the linear PVD source (e.g., the linear PVD source 102) can be used to provide a stream of material flux (e.g., stream 108) including a material (e.g., the material 204) and to deposit the material on a substrate (e.g., the substrate 106), which can be disposed on the support surface of the substrate support (e.g., the substrate support 104) at 1004. At 1006, the stream of material flux passes into the deposition chamber (e.g., the deposition chamber 308) through the opening (e.g., the opening 306) between the linear PVD source and the deposition chamber. Optionally, the range of angles of travel of the material within the elongate dimension of the stream can be limited.

Continuing at 1006, the substrate support can be moved (e.g., either along a plane of the support surface of the substrate support or along an axis that is perpendicular to the plane of the support surface of the substrate support) linearly from a first position (for example, where the stream of material flux is proximate a first side of the substrate), through the stream of material flux to a second position (for example, where the stream of material flux is proximate a second side of the substrate opposite the first side). For example, the first position can position the substrate completely out of the stream of material flux, or at least a portion of the stream of material flux. Moreover, the second position can also position the substrate completely out of the stream of material flux, or at least a portion of the stream of material flux. Continuing at 1006, the amount of deposition of material on the substrate depends upon the deposition rate and the rate of speed of the linear movement of the substrate through the stream of material flux. The substrate can pass through the stream of material flux once (e.g., move from the first position to the second position once) or multiple times (e.g., move from the first position to the second position, then move from the second position to the first position, etc.) in order to deposit a desired thickness of material on the substrate. Optionally, the substrate can be rotated between passes (e.g., after reaching the first position or the second position at the end of linear movement) or while passing through the stream of material flux (e.g., at the same time as the linear movement from the first position to the second position).

Linear slides (e.g., 310) or shafts (e.g., 610) coupling the substrate support 104 to the position control mechanism 322 are supported by and travel through a gas-cushioned bearing 370 having an inert gas provided as the gas for the bearing (e.g., by the inert gas source 372). As such, each layer of deposited material will have reduced contamination or defects due to oxygen as compared to when using air or CDA as the gas for the bearing.

In embodiments where two streams of material flux are provided (e.g., as shown in FIGS. 7-8), the streams can be alternated or provided simultaneously. In addition, the orientation of the substrate can be rotationally fixed or variable. For example, in some embodiments, the two streams of material flux can alternately provide the same material or different materials to be deposited asymmetrically on the substrate as shown in FIGS. 2A-2B. The substrate can be rotationally fixed while the first stream of material flux is provided in a first pass through the first stream of material flux. The substrate can then be rotated 180 degrees and subsequently be rotationally fixed while the second stream of material flux is provided in a first pass through the second stream of material flux. If desired, after completion of the first pass through the second stream of material flux, the substrate can again be rotated 180 degrees and then held rotationally fixed in a second pass through the first stream of material flux. The rotation of the substrate and passes through either the first or the second streams of material flux can continue until a desired thickness of material is provided. In cases where the first and second streams of material flux provide different materials to be deposited, the rate of movement of the substrate support can be the same or different when passing through the first stream of material flux as compared to passing through the second stream of material flux.

In some embodiments, the substrate can be rotated continuously while passing through the first or the second stream of material flux (e.g., at the same time as the linear movement from the first position to the second position or from the second position to the first position) to achieve a deposition profile similar to that shown in FIGS. 2C-2D.

While the foregoing is directed to embodiments of the present disclosure, other and further embodiments of the disclosure may be devised without departing from the basic scope thereof.

1. An apparatus for physical vapor deposition (PVD), comprising:
a linear PVD source to provide a stream of material flux comprising material to be deposited on a substrate; and
a substrate support having a support surface to support the substrate, wherein the substrate support is configured to support the substrate at a non-perpendicular angle to the linear PVD source, and wherein the substrate support and linear PVD source are movable with respect to each other either along a plane of the support surface of the substrate support, or along an axis that is perpendicular to the plane of the support surface of the substrate support, sufficiently to cause the stream of material flux to move completely over a surface of the substrate disposed on the substrate support during operation,
wherein the substrate support moves on at least one of a linear slide or shaft that is supported by and travels through a gas-cushioned bearing having an inert gas as a cushioning gas.

2. The apparatus of claim 1, wherein the inert gas is a noble gas.

3. The apparatus of claim 1, wherein the inert gas is nitrogen gas (N₂).

4. The apparatus of claim 1, wherein the gas-cushioned bearing is coupled to an inert gas source.

5. The apparatus of claim 1, wherein the substrate support moves on at least one of two linear slides or two shafts that are supported by and travel through at least two corresponding gas-cushioned bearings having a respective inert gas as the cushioning gas.

6. The apparatus of claim 5, wherein each of the at least two corresponding gas-cushioned bearings is coupled to a corresponding inert gas source.

7. The apparatus of claim 1, wherein the substrate support can rotate within the plane of the support surface.

8. The apparatus of claim 1, further comprising:
a second linear PVD source to provide a second stream of material flux comprising material to be deposited on the substrate at a non-perpendicular angle to the plane of the support surface.

9. The apparatus of claim 1, further comprising:
a position control mechanism coupled to the linear slide to control the position of the substrate support.

10. A method for performing physical vapor deposition (PVD), comprising:
providing a stream of material flux comprising a material to be deposited on a substrate into a processing volume of a PVD chamber by a linear PVD source;
supporting the substrate, at a non-perpendicular angle to the linear PVD source, using a substrate support disposed within the processing volume, wherein the substrate support moves on at least one of a linear slide or shaft that is supported by and travels through a gas-cushioned bearing having an inert gas as a cushioning gas; and
causing the stream of material flux to move over and be deposited on a working surface of the substrate by moving the substrate support along a plane of a support surface of the substrate support or along an axis that is perpendicular to the plane of the support surface of the substrate support.

11. The method of claim 10, wherein the inert gas is at least one of argon, helium, or nitrogen.

12. The method of claim 10, wherein the gas-cushioned bearing is coupled to an inert gas source.

13. The method of claim 12, wherein the substrate support moves on at least one of two linear slides or two shafts that are supported by and travel through at least two corresponding gas-cushioned bearings having a respective inert gas as the cushioning gas.

14. The method of claim 13, wherein each of the at least two corresponding gas-cushioned bearings is coupled to a corresponding inert gas source.

15. The method of claim 10, further comprising:
rotating the substrate support within the plane of the support surface during at least one of while depositing the material on the substrate, or between sequential depositions of material on the substrate.

16. The method of claim 10, further comprising:
providing a second stream of material flux comprising material to be deposited on the substrate at a non-perpendicular angle to the plane of the support surface using a second linear PVD source.

17. A nontransitory computer readable storage medium having stored thereon instructions which when executed by a controller perform a method for physical vapor deposition (PVD), comprising:
providing a stream of material flux comprising a material to be deposited on a substrate into a processing volume of a PVD chamber by a linear PVD source;
supporting the substrate, at a non-perpendicular angle to the linear PVD source, using a substrate support disposed within the processing volume, wherein the substrate support moves on at least one of a linear slide or shaft that is supported by and travels through a gas-cushioned bearing having an inert gas as a cushioning gas; and
causing the stream of material flux to move over and be deposited on a working surface of the substrate by moving the substrate support along a plane of the support surface of the substrate support or along an axis that is perpendicular to the plane of the support surface of the substrate support.

18. The nontransitory computer readable storage medium of claim 17, wherein the inert gas is at least one of argon, helium, or nitrogen.

19. The nontransitory computer readable storage medium of claim 17, wherein the gas-cushioned bearing is coupled to an inert gas source.

20. The nontransitory computer readable storage medium of claim 17, further comprising:
rotating the substrate support within the plane of the support surface during at least one of while depositing the material on the substrate, or between sequential depositions of material on the substrate.
